(19) United States
(12) Patent Application Publication
(10) Pub. No.: US 2025/0001467 A1
(43) Pub. Date: Jan. 2, 2025

(54) SUBSTRATE PROCESSING METHOD

(71) Applicant: TES CO., LTD, Yongin-si (KR)

(72) Inventors: In-Il JUNG, Yongin-si (KR); Seung-Min OH, Yongin-si (KR); Jong-Seok LEE, Yongin-si (KR)

(73) Assignee: TES CO., LTD, Yongin-si (KR)

(21) Appl. No.: 18/747,466

(22) Filed: Jun. 19, 2024

(30) Foreign Application Priority Data
Jun. 30, 2023 (KR) 10-2023-0085359

(51) Int. Cl. B08B 7/00; B08B 7/02; H01L 21/02

(52) U.S. Cl. CPC B08B 7/0021; B08B 7/02; H01L 21/02101

(57) ABSTRACT

The present disclosure relates to a substrate processing method, and more particularly, to a substrate processing method of a substrate processing device using a supercritical fluid, to reduce damage or defects to a substrate when the supercritical fluid is supplied into the chamber.

### CROSS-REFERENCE TO RELATED APPLICATION

This application is based on and claims priority under 35 U.S.C. § 119 to Korean Patent Application No. 10-2023-0085359, filed on Jun. 30, 2023, in the Korean Intellectual Property Office, the disclosure of which is incorporated by reference herein in its entirety.

### TECHNICAL FIELD

The present disclosure relates to a substrate processing method, and more particularly, to a substrate processing method for reducing damage or defects to a substrate when supercritical fluid is supplied into a chamber in a substrate processing method of a substrate processing apparatus using a supercritical fluid.

### BACKGROUND

In general, when large-scale/high-density semiconductor devices such as large-scale integration (LSI) are manufactured on a surface of a semiconductor wafer, it is necessary to form an ultrafine pattern on the surface of the wafer.

These ultrafine patterns may be formed by performing various processes of exposing, developing, and cleaning a wafer coated with resist, patterning the resist, and then etching the wafer to transfer the resist pattern to the wafer.

After this etching, the wafer is cleaned to remove dust or natural oxide films on the wafer surface. The cleaning process is performed by immersing the wafer with a surface on which a pattern is formed in a treatment liquid such as a chemical solution or a rinse liquid or by supplying the treatment liquid to the wafer surface.

However, as semiconductor devices become more highly integrated, pattern collapse, in which the pattern on the resist or the wafer surface collapses, occurs when the treatment liquid is dried after cleaning.

This pattern collapse corresponds to a phenomenon in which patterns 11, 12, and 13 collapse toward a side at which a large amount of the treatment liquid remains due to an imbalance in the capillary force of stretching the patterns 11, 12, and 13 to the left and right when the treatment liquid on the left and right sides of the patterns 11, 12, and 13 dries unevenly during the process of drying a treatment liquid 10 remaining on a surface of a substrate S after cleaning as shown in FIG. 12.

FIG. 12 shows a state in which a treatment liquid in left and right outer regions of an upper surface of the substrate S, in which a pattern is not formed, is completely dried, while the treatment liquid 10 remains in a gap between the patterns 11, 12, and 13. As a result, the patterns 11 and 13 on both the left and right sides collapse toward the inside due to the capillary force received from the treatment liquid 10 remaining between the patterns 11, 12, and 13.

The capillary force causing the pattern collapse described above is caused by an atmospheric atmosphere surrounding the substrate S after cleaning and a surface tension of the treatment liquid functioning at a liquid/gas interface with the treatment liquid remaining between patterns.

Therefore, recently, a treatment method of drying the treatment liquid by using a fluid in a supercritical state (hereinafter referred to as ‘supercritical fluid’) in which an interface between gas or liquid is not formed has attracted attention.

In a conventional drying method using only temperature control in a pressure and temperature phase diagram of FIG. 13, a gas-liquid equilibrium line is necessarily passed as shown by a hidden line, and in this case, capillary force is generated at a gas-liquid interface.

In contrast, when a fluid is dried through a supercritical state by using both temperature and pressure control of the fluid, a gas-liquid equilibrium line is not passed, and thus it is possible to dry a substrate in a state essentially free of capillary force.

With regard to drying using a supercritical fluid with reference to FIG. 13, when the pressure of a liquid is raised from A to B and the temperature is then raised from B to C, the liquid is converted into a supercritical state C without passing the gas-liquid equilibrium line. When the drying process is completed, the pressure of the supercritical fluid is lowered and converted to gas D without passing the gas-liquid equilibrium line.

When a supercritical fluid is used, if the supercritical fluid is supplied into the chamber, defects to the substrate may occur due to the high pressure and flow rate of the supercritical fluid at the beginning of supply. To this end, the conventional device supplies a supercritical fluid through a lower side of a chamber in a pressurization operation and supplies the supercritical fluid through an upper side of the chamber in an equal pressure operation, but defects to the substrate cannot be reduced even when the supercritical fluid is supplied through the upper side of the chamber in the equal pressure operation.

This means that when an organic solvent is supplied through the upper side of the chamber without sufficient substitution (mixing) by the supercritical fluid in the equal pressure operation after the supercritical fluid is supplied through the lower side of the chamber in the pressurization operation, flow separation of the organic solvent occurs while the organic solvent is rapidly mixed by a flow of the supercritical fluid in an area in which two phases (liquid-supercritical) coexist, and thus a lot of defects may occur especially in a central area of the substrate to which the supercritical fluid is supplied.

### SUMMARY

To overcome the above problem, an object of the present disclosure is to provide a substrate processing method for reducing damage to a substrate due to a high pressure and flow rate of a supercritical fluid when the supercritical fluid is supplied to a chamber.

According to an aspect of the present disclosure, a substrate processing method of a substrate processing apparatus including a chamber for performing a processing process on a substrate using a supercritical fluid includes a pressurization operation in which the fluid is supplied through a lower side of the chamber to pressurize the fluid to a predetermined process pressure, a process operation in which the fluid is supplied toward the chamber and is simultaneously discharged, and a processing process is performed on the substrate, and a depressurization operation in which the fluid is discharged from an inside of the chamber, wherein the fluid is supplied to the chamber through a lower side of the chamber during at least some sections in the process operation.

The process operation may include a first supply operation of supplying the fluid to the chamber through a lower side of the chamber, and a second supply operation of supplying the fluid to the chamber through an upper side of the chamber.

The first supply operation may be positioned in a predetermined section of the process operation.

The process operation may include alternatively repeating the first supply operation and the second supply operation.

The process operation includes supplying the fluid to the chamber through only the lower side of the chamber.

The process operation may include generating a pulse wave by the fluid inside the chamber. In this case, the process operation includes performing an exhaust operation of lowering a pressure inside the chamber to a predetermined pressure and subsequently performing a first supply operation of supplying the fluid to the chamber through the lower side of the chamber to a pressure inside the chamber to the process pressure again.

### BRIEF DESCRIPTION OF THE DRAWINGS

Embodiments will be more clearly understood from the following detailed description taken in conjunction with the accompanying drawings in which:

FIG. 1 is a block diagram showing a configuration of a substrate processing apparatus using a supercritical fluid according to an embodiment of the present disclosure;

FIG. 2 is a side cross-sectional view showing a configuration of a chamber in FIG. 1;

FIG. 3 is a graph showing pressure changes inside a chamber according to a conventional substrate processing method;

FIGS. 4 to 6 are diagrams for explaining an operation of a substrate processing apparatus in each operation of a processing process for a substrate;

FIGS. 7 to 10 are graphs showing pressure changes inside a chamber according to a substrate processing method according to the present disclosure;

FIGS. 11A and 11B are diagrams showing a degree of defects to a substrate when the substrate is processed according to a conventional substrate processing method and a substrate processing method according to the present disclosure;

FIG. 12 is a schematic diagram showing a state in which a pattern collapses when the pattern on a substrate is dried according to the related art; and

FIG. 13 is a state diagram showing pressure and temperature changes in a fluid in a processing process using a supercritical fluid.

### DETAILED DESCRIPTION OF THE EMBODIMENTS

Hereinafter, a structure of a substrate processing apparatus according to an embodiment of the present disclosure will be examined in detail with reference to the drawings.

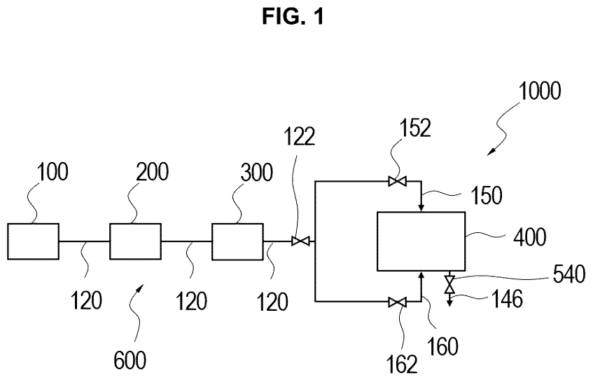

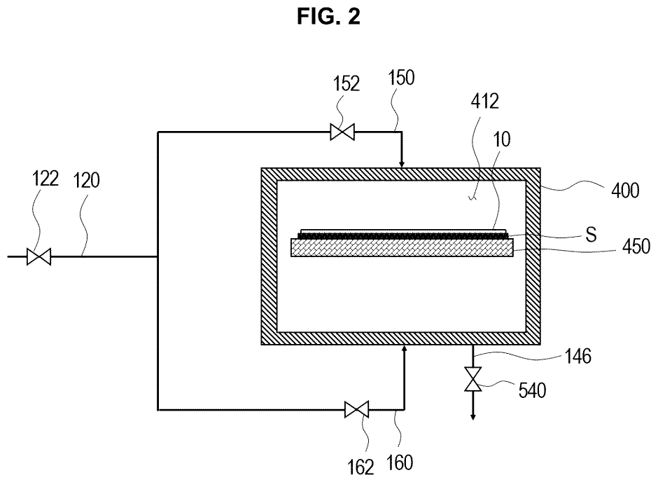

FIG. 1 is a block diagram showing a configuration of a substrate processing apparatus 1000 according to the related art, and FIG. 2 is a side cross-sectional view showing a configuration of a chamber 400.

The substrate processing apparatus 1000 using a supercritical fluid performs a processing process on a substrate S by using a fluid in a supercritical state. Here, a fluid in a supercritical state corresponds to a fluid with a phase in which a material reaches a critical state, that is, a state exceeding a critical temperature and a critical pressure. The fluid in a supercritical state has a molecular density close to that of a liquid, but a viscosity close to that of a gas. Therefore, since the fluid in a supercritical state has excellent diffusion, penetration, and dissolving power, which is advantageous for chemical reactions and does not apply surface tension to a microstructure due to almost no surface tension, the fluid in a supercritical state not only has excellent drying efficiency during a drying process of semiconductor devices, but also is capable of avoiding pattern collapse, and thus may be very useful.

In the present disclosure, carbon oxide (CO₂) may be used as a supercritical fluid. Carbon dioxide has a critical temperature of approximately 31.1° C. and a relatively low critical pressure of 7.38 Mpa, and thus it is advantageous that carbon dioxide is easily converted to a supercritical state, the state of carbon dioxide is controlled by adjusting the temperature and the pressure thereof, and carbon dioxide is inexpensive.

Carbon dioxide is non-toxic, harmless to the human body, and has properties of being non-flammable and inert. Since carbon dioxide in a supercritical state has a diffusion coefficient that is approximately 10 to 100 times higher than that of water or other organic solvents, carbon dioxide has excellent permeability, allows rapid substitution of organic solvents, and has almost no surface tension, and thus has properties that are advantageous for use in a drying process. It is possible to convert carbon dioxide used in the drying process into a gaseous state, separate the organic solvent, and reuse the same, thus reducing a burden in terms of environmental pollution.

Referring to FIGS. 1 and 2, the substrate processing apparatus 1000 may include the chamber 400 that provides a processing space 412 in which a processing process for the substrate S coated with a treatment liquid or organic solvent 10 (hereinafter referred to as ‘organic solvent’) by using a liquid in a supercritical state, and a fluid supply unit 600 that supplies a fluid to the chamber 400.

The fluid supply unit 600 may supply a fluid to the chamber 400 through a main supply line 120 by adjusting at least one of the temperature and pressure of the fluid.

For example, the fluid supply unit 600 may include a fluid storage unit 100 that stores the fluid, and the main supply line 120 connecting the fluid storage unit 100 and the chamber 400 to each other.

In this case, a pressure controller 200 and a temperature controller 300 may be located along the main supply line 120. In this case, the pressure controller 200 may include, for example, a pressure pump, and the temperature controller 300 may include a heater heating the fluid or a heat exchanger.

The main supply line 120 may further include a detector (not shown) that detects at least one of the pressure and temperature of the fluid. The pressure and temperature of the fluid flowing in the main supply line 120 may be adjusted according to the pressure and temperature detected by the detector. To this end, the substrate processing apparatus 1000 according to an embodiment of the present disclosure may include a controller (not shown) that controls the pressure controller 200 and the temperature controller 300. The controller may control the pressure controller 200 and the temperature controller 300 based on the pressure and temperature detected by the detector.

When a processing process is performed on the substrate S, the temperature and pressure of the processing space 412 of the chamber 400 need to be maintained above the critical temperature and critical pressure to convert the fluid supplied into the chamber 400 into a supercritical state.

To this end, while the fluid moves along the main supply line 120, the fluid may be pressurized to a critical pressure or higher by the temperature controller 300, and also the fluid may be heated to a critical temperature or higher by the temperature controller 300.

The main supply line 120 may include a first supply line 150 connected to an upper side of the chamber 400 and a second supply line 160 connected to a lower side of the chamber 400. The first supply line 150 may be connected to approximately a central part of the upper side of the chamber 400, and similarly, the second supply line 160 may be connected to approximately a central part of the lower side of the chamber 400. Before the main supply line 120 branches into the first supply line 150 and the second supply line 160, a supply valve 122 may be provided in the main supply line 120.

The first supply line 150 may include a first valve 152 configured to control on/off of a fluid flow, and likewise, the second supply line 160 may include a second valve 162 configured to control on/off of a fluid flow.

Although not shown in the drawing, the first supply line 150 may include a first filter that filters foreign substances from the fluid, and the second supply line 160 may include a second filter that similarly filters foreign substances from the fluid. In this case, the first filter may be located at a front end of the first valve 152 in a fluid flow direction of the first supply line 150. The second filter may also be located at a front end of the second valve 162 in a fluid flow direction of the second supply line 160.

The chamber 400 may further include a discharge line 146 for discharging the fluid in the processing space 412 to the outside. During the processing process for the substrate S or when the processing process is completed, fluid may be discharged from the inside of the chamber 400 to the outside through the discharge line 146. The discharge line 146 may include a discharge valve 540, and may include, for example, a proportional valve.

The discharge line 146 may be spaced apart from the central part of the lower side of the chamber 400. As described above, the second supply line 160 may be connected to the central part of the lower side of the chamber 400, and thus the discharge line 146 may be spaced apart from the central part of the lower side of the chamber 400 to avoid interference with the second supply line 160.

The chamber 400 may provide the processing space 412 for performing a processing process such as a drying process on the substrate S by using a fluid in a supercritical state. The chamber 400 may have an opening (not shown) formed at one side and may be formed of a material to process a high-pressure process for the substrate S inside the chamber 400.

The processing space 412 of the chamber 400 is maintained in a sealed state, and thus the pressure of the fluid supplied to the processing space 412 may be maintained above the critical pressure.

The chamber 400 may further include a heater (not shown) to maintain the temperature of the processing space 412 above a certain temperature. The heater may maintain the temperature of the processing space 412 or the temperature of the fluid accommodated in the processing space 412 above a critical temperature during the process for the substrate S.

The chamber 400 may include a tray 450 that supports the substrate S.

The tray 450 may be retracted into the processing space 412 of the chamber 400 through the above-described opening of the chamber 400, or is extended out of the chamber 400 through the opening in the processing space 412.

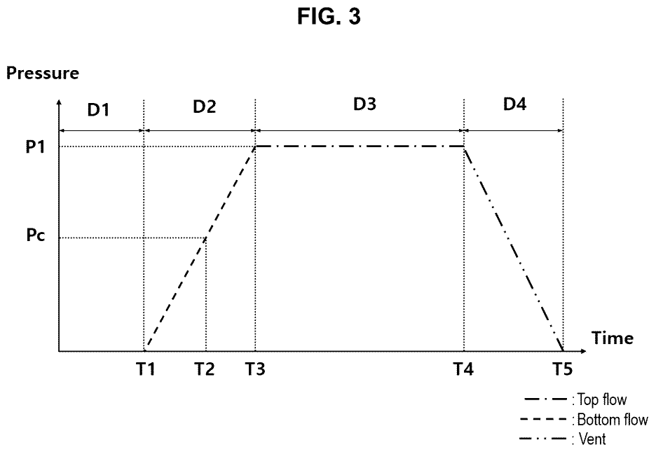

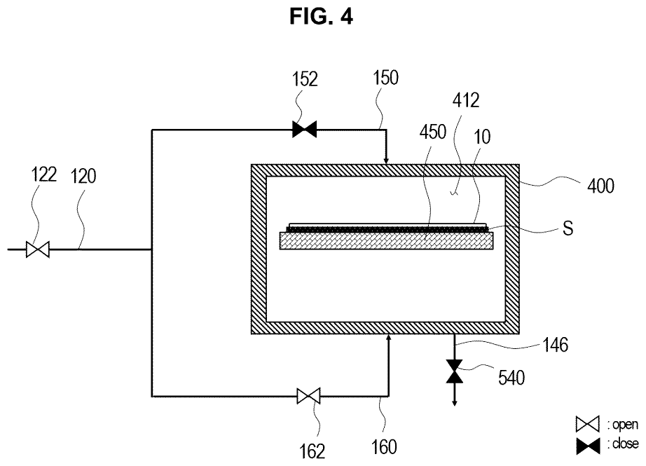

FIG. 3 is a graph showing pressure changes inside the chamber 400 according to a process for the substrate S in a conventional substrate processing method in the substrate processing apparatus 1000. FIGS. 4 to 6 are diagrams for explaining an operation of the substrate processing apparatus 1000 in each operation in a processing process for a substrate. Hereinafter, a processing process for the substrate S of the substrate processing apparatus 1000 will be described with reference to the drawings.

Referring to FIG. 3, in the case of a preparation operation D1: 0 to T1 in which the process for the substrate S begins and the tray 450 is retracted and docked inside the chamber 400, the pressure inside the chamber 400 may correspond to atmospheric pressure.

Then, a pressurization operation D2: T1 to T3 in which the pressure inside the chamber 400 increases follows.

In the pressurization operation, a high-pressure fluid may be supplied into the chamber 400, and the fluid may not be discharged from the chamber 400 to the outside. Accordingly, the pressure inside the chamber 400 increases and reaches a predetermined pressure through a threshold pressure Pc.

For example, as shown in FIG. 4, fluid may be supplied through the lower side of the chamber 400 by opening the supply valve 122 of the main supply line 120, closing the first valve 152 of the first supply line 150 and the discharge valve 540 of the discharge line 146, and opening the second valve 162 of the second supply line 160.

The fluid may be supplied into the chamber 400 through the second supply line 160 described above until the pressure of the chamber 400 reaches a predetermined process pressure P1.

When the fluid is supplied from the pressurization operation through the upper side of the chamber 400, the fluid may be supplied directly from the upper side of the chamber 400 towards the substrate S. In this case, a high-velocity fluid may destabilize the organic solvent on the substrate S, and further, the pattern (not shown) formed on the substrate S may be defected by the high-velocity fluid.

Accordingly, in the pressurization operation, fluid may be supplied from the lower side of the chamber 400 through the second supply line 160. When the fluid is supplied through the lower side of the chamber 400, the fluid is blocked by the tray 450 and is not directly supplied to the substrate S to prevent defects to the pattern on the substrate S.

Referring to FIG. 3, the pressurization operation D2 is followed by the process operation D3.

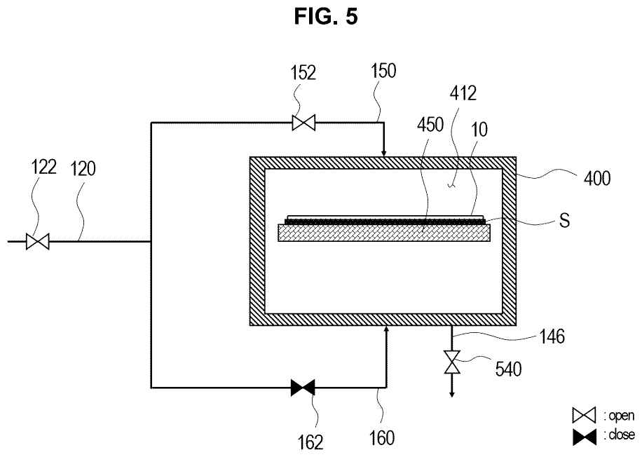

In the process operation D3, as shown in FIG. 5, fluid may be supplied through the upper side of the chamber 400 in a state in which the supply valve 122 of the main supply line 120 is maintained in an open state, the first valve 152 of the first supply line 150 and the discharge valve 540 of the discharge line 146 are opened, and the second valve 162 of the second supply line 160 is closed.

In this case, while fluid is continuously supplied into the chamber 400 through the first supply line 150, fluid may be discharged out of the chamber 400 through the discharge line 146.

Additionally, an amount of the supplied fluid to the chamber 400 may be discharged through the discharge line 146 to maintain constant the pressure inside the chamber 400.

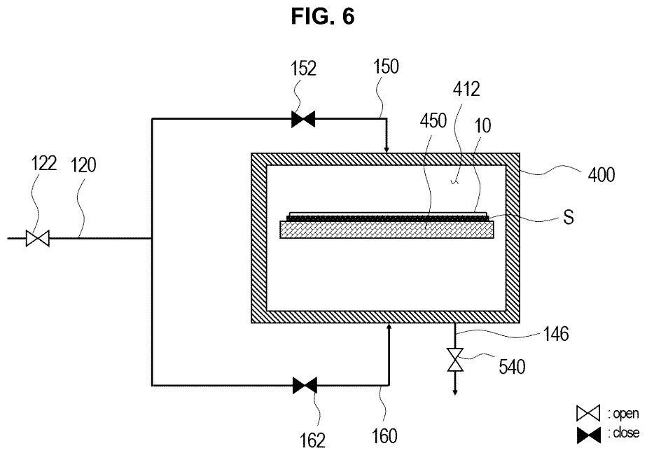

The process operation D3 described above may be followed by a depressurization operation D4 as shown in FIG. 3. In the depressurization operation D4, as shown in FIG. 6, the fluid inside the chamber 400 may be discharged by closing both the first valve 152 of the first supply line 150 and the second valve 162 of the second supply line 160 and opening the discharge valve 540 of the discharge line 146.

That is, instead of supplying fluid into the chamber 400, the fluid may be discharged to the outside of the chamber 400 through the discharge line 146 to reduce the pressure inside the chamber 400.

As described above, in the pressurization operation D2, fluid may be supplied through the lower side of the chamber 400 to reduce defects to the substrate S, and fluid may be supplied through the upper side of the chamber 400 in the process operation D3 in which pressure inside the chamber 400 reaches the process pressure P1.

However, as seen from a test of the present inventor, when fluid is supplied through the upper side of the chamber 400 in the process operation D3, a lot of defects occur in the substrate S even after the pressure inside of the chamber 400 reaches the process pressure P1.

It is understood that even when the pressure inside of the chamber 400 reaches the process pressure P1, defects to the substrate S may occur due to the high-pressure and high-velocity fluid supplied through the upper side of the chamber 400.

Accordingly, the present disclosure provides a substrate processing method that reduces defects to the substrate S caused by fluid when the fluid is supplied into the chamber 400.

The substrate processing method according to the present disclosure may include the pressurization operation D2 in which the fluid is supplied through the lower side of the chamber 400 and is pressurized with a predetermined process pressure P1, the process operation D3 in which the fluid is supplied toward the chamber 400 and is simultaneously discharged, and a processing process is performed on the substrate S, and the depressurization operation D4 in which the fluid is discharged from the inside of the chamber 400, and during at least some sections of the process operation D3, the fluid may be supplied to the chamber 400 through the lower side of the chamber 400.

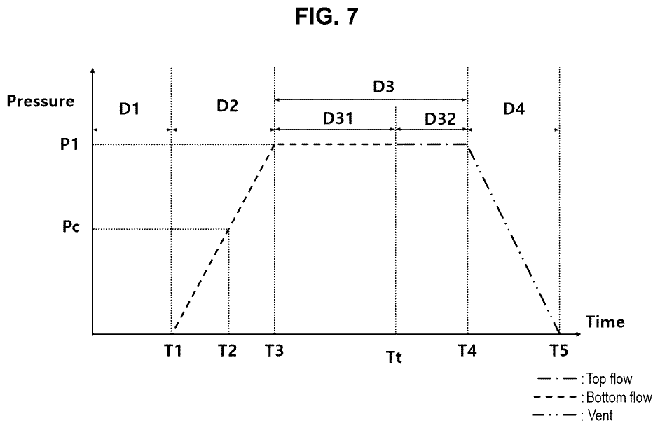

FIGS. 7 to 10 are graphs showing pressure changes inside the chamber 400 in a substrate processing method according to the present disclosure. In the drawing, a dotted line is shown to supply fluid to the lower side of the chamber 400 (Bottom flow), a one-dotted line is shown to supply fluid to the upper side of the chamber 400 (Top flow), and a two-dot chain line is shown to discharge fluid from the chamber 400.

As shown in FIG. 7, the process operation D3 may include a first supply operation D31 in which the fluid is supplied to the chamber 400 through the lower side of the chamber 400, and a second supply operation D32 in which the fluid is supplied to the chamber 400 through the upper side of the chamber 400. Driving of the chamber 400 and the substrate processing apparatus 1000 in the first supply operation D31 and the second supply operation D32 has already been described in detail in FIGS. 4 and 5, and thus repeated descriptions will be omitted.

For example, the first supply operation D31 may be followed by the pressurization operation D2 described above, and when a predetermined transition time Tt is reached, the second supply operation D32 may be performed. The second supply operation D32 may be followed by the depressurization operation D4 described above. In the present embodiment, the above-described first supply operation D31 and second supply operation D32 may be performed once each.

In other words, in the present disclosure, the fluid is not supplied to the chamber 400 directly through the upper side of the chamber 400 in the process operation D3, but instead, a time taken to supply the fluid to the lower side of the chamber 400 may be increased as compared to the conventional time, thereby reducing defects to the substrate S as much as possible.

The transition time Tt may be determined as a predetermined time from a start time T3 of the process operation D3 or may be determined in consideration of various process conditions for the substrate S.

Although not shown in the drawing, the first supply operation D31 may be located in a predetermined section of the process operation D3 and performed.

In other words, in FIG. 7, the first supply operation D31 is described as being located in an initial section of the process operation D3, but the present disclosure is not limited thereto, and the first supply operation D31 may be located in a middle or late section of the process operation D3.

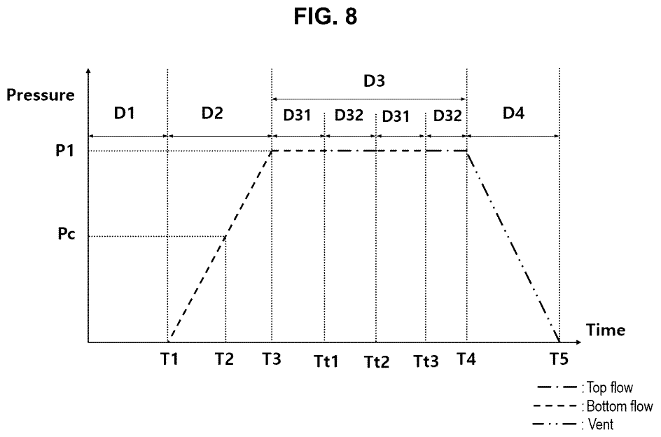

As shown in FIG. 8, in the process operation D3, the first supply operation D31 and the second supply operation D32 may be alternately repeated and performed.

For example, the above-described first supply operation D31 and second supply operation D32 may be alternately repeated and each performed twice. That is, the pressurization operation D2 may be followed by the first supply operation D31, when a first transition time Tt1 is reached, the second supply operation D32 may be performed, when a second transition time Tt2 is reached, the first supply operation D31 may be performed, and when a third transition time Tt3 is reached, the second supply operation D32 may be performed.

The number of repetitions of the first supply operation D31 and the second supply operation D32 may be described as an example and may be modified appropriately.

As shown in FIG. 8, when the first supply operation D31 and the second supply operation D32 are alternately repeated, a flow of the fluid within the chamber 400 continuously changes, and there is also an effect of reducing a dead zone in which the above-described organic solvent 10 is not replaced on an upper surface of the substrate S.

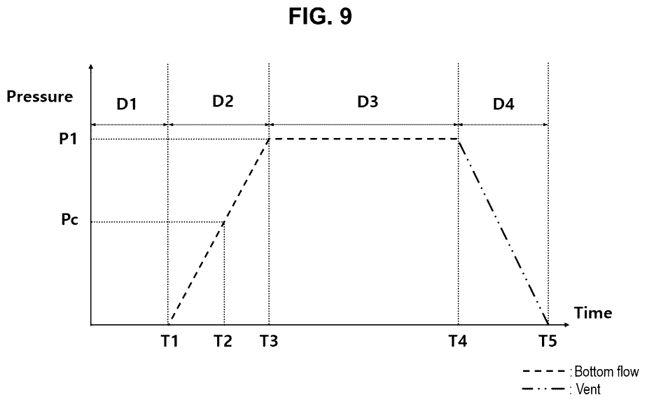

As shown in FIG. 9, it is also possible to supply the fluid to the chamber 400 only through the lower side of the chamber 400 in the process operation D3.

In this case, the fluid is supplied only through the lower side of the chamber 400, and thus there is an advantage in that defects to the substrate S are minimized as possible as.

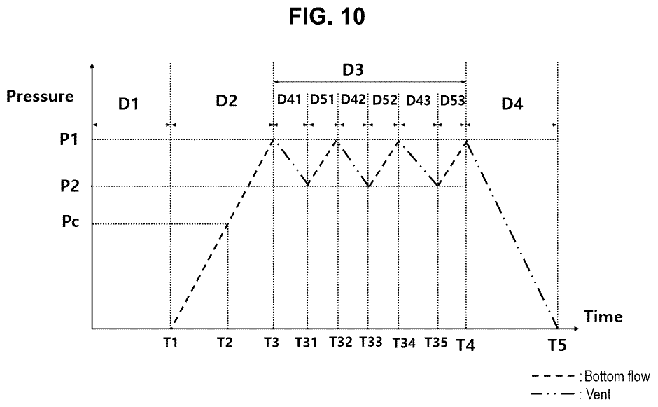

As shown in FIG. 10, the chamber 400 may be driven to generate a pulse wave inside the chamber 400 in the process operation D3.

For example, referring to FIG. 10, in the process operation D3, an exhaust operation D41 in which the fluid inside the chamber 400 is lowered to a predetermined pressure P2 may be performed, and subsequently, a first supply operation D5 in which the fluid is supplied to the chamber 400 through the lower side of the chamber 400 to pressurize the inside of the chamber 400 to the process pressure P1 again.

In this case, the above-described exhaust operations D42 and D43 and first supply operations D52 and D53 may be performed repeatedly.

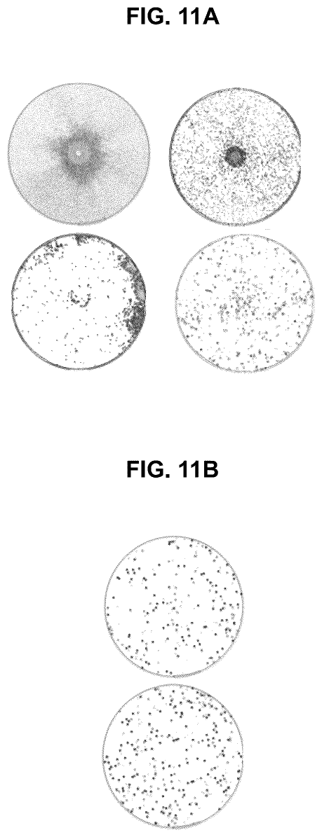

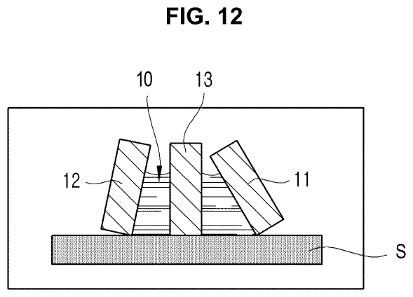

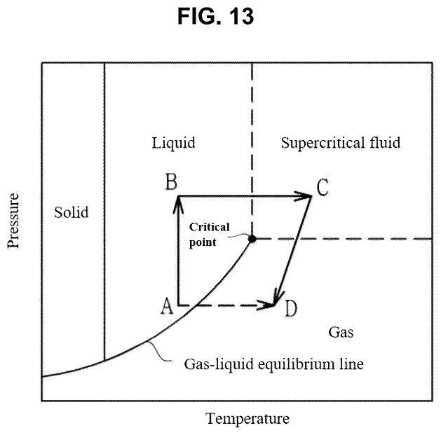

FIGS. 11A and 11B correspond to a diagram showing a degree of defects to the substrate S when the substrate S is processed according to a conventional substrate processing method and a substrate processing method according to the present disclosure. FIG. 11A shows a degree of defects to the substrate S according to the conventional substrate processing method. FIG. 11B shows a degree of defects to the substrate S according to the substrate processing method according to the present disclosure.

As seen from FIGS. 11A and 11B, in the case of substrate S processed using the conventional substrate processing method, intensive defects occur at a central part of the substrate S, and a lot of defects occur as a whole.

On the other hand, in the case of the substrate S processed according to the substrate processing method according to the present disclosure. defects to the central part of the substrate S are significantly reduced, and furthermore, it may be seen that overall defects are relatively reduced compared to the conventional method.

According to the present disclosure having the configuration described above, when a supercritical fluid is supplied to a chamber, the pressurization operation may be followed by at least one section of the process operation, in which the fluid is supplied through the lower side of the chamber, thereby reducing defects to the substrate.

Although the present disclosure has been described above with reference to exemplary embodiments, those skilled in the art may modify and change the present disclosure in various ways without departing from the spirit and scope of the present disclosure as set forth in the claims described below. Therefore, when the modified implementation basically includes the elements of the claims of the present disclosure, it should be considered to be included in the technical scope of the present disclosure.

What is claimed is:

1. A substrate processing method of a substrate processing apparatus including a chamber for performing a process on a substrate using a supercritical fluid, the method comprising:
a pressurization operation in which the fluid is supplied through a lower side of the chamber to pressurize the fluid to a predetermined process pressure;
a process operation in which the fluid is supplied into the chamber and is simultaneously discharged, and a process is performed on the substrate; and
a depressurization operation in which the fluid is discharged from the chamber,
wherein the fluid is supplied to the chamber through a lower side of the chamber during at least sections of the process operation.

2. The method of claim 1, wherein the process operation includes:
a first supply operation of supplying the fluid to the chamber through a lower side of the chamber; and
a second supply operation of supplying the fluid to the chamber through an upper side of the chamber.

3. The method of claim 2, wherein the first supply operation is positioned in a predetermined section of the process operation.

4. The method of claim 2, wherein the process operation includes alternatively repeating the first supply operation and the second supply operation.

5. The method of claim 1, wherein the process operation includes supplying the fluid to the chamber through only the lower side of the chamber.

6. The method of claim 1, wherein the process operation includes generating a pulse wave by the fluid inside the chamber.

7. The method of claim 6, wherein the process operation includes performing an exhaust operation of lowering a pressure inside the chamber to a predetermined pressure and subsequently performing a first supply operation of supplying the fluid to the chamber through the lower side of the chamber to a pressure inside the chamber to the process pressure again.
